(19) United States
(12) Patent Application Publication
(10) Pub. No.: US 2025/0266079 A1
(43) Pub. Date: Aug. 21, 2025

(54) APPARATUSES AND METHODS FOR DQ TERMINAL PSEUDO-RANDOM BIT STREAM VARIATION

(71) Applicant: Micron Technology, Inc., Boise, ID (US)

(72) Inventors: Linh H. Nguyen, Boise, ID (US); Eric J. Stave, Meridian, ID (US)

(73) Assignee: Micron Technology, Inc., Boise, ID (US)

(21) Appl. No.: 19/022,840

(22) Filed: Jan. 15, 2025

Related U.S. Application Data
(60) Provisional application No. 63/555,555, filed on Feb. 20, 2024.

(51) Int. Cl. G11C 11/4076

(52) U.S. Cl. CPC G11C 11/4076

(57) ABSTRACT

A memory device includes a pseudo-random bit stream (PRBS) generator circuit with a linear feedback shift register (LFSR) which has a number of latches. The data terminals of the memory are associated with a LFSR variation circuit which selects one of the latches and couples the selected latch to the associated data terminal. By varying settings such as which latch each of the DQ terminals are coupled to, the sequence of bits of the PRBS may be varied between the data terminals.

### CROSS-REFERENCE TO RELATED APPLICATIONS

This application claims the filing benefit of U.S. Provisional Application No. 63/555,555, filed Feb. 20, 2024. This application is incorporated by reference herein in its entirety and for all purposes.

### BACKGROUND

Information may be stored on memory cells of a memory device. The memory cells may be organized at the intersection of word lines (rows) and bit lines (columns). During access operations, the memory accesses information in the memory cells for example to write new information to those memory cells as part of a write operation or to read information from the memory cells as part of a read operation.

Various operations such as testing or training operations may take advantage of a pseudo-random bit stream (PRBS) along one or more of the data terminals. For example, in order to train a data strobe signal used to latch data along the data terminals. The memory includes a PRBS generator circuit which supplies PRBS to the data terminals when enabled. There may be a need to increase the variation of the PRBS between different data terminals to help increase the difference between the stream of bits along different data terminals.

### BRIEF DESCRIPTION OF THE DRAWINGS

FIG. 1 is a block diagram of a memory system according to some embodiments of the present disclosure.

FIG. 2 is a block diagram of a PRBS generator circuit according to some embodiments of the present disclosure.

FIG. 3 is a schematic diagram of a PRBS generator circuit with non-overlapping latch selection according to some embodiments of the present disclosure.

FIG. 4 is a schematic diagram of a PRBS generator circuit with overlapping latch selections according to some embodiments of the present disclosure.

FIG. 5 is a schematic diagram of a PRBS generator circuit with crossover selection between two LFSR circuits according to some embodiments of the present disclosure.

FIG. 6 is a table of example operations of a PRBS generator circuit according to some embodiments of the present disclosure.

FIG. 7 is a flow chart of a method according to some embodiments of the present disclosure.

### DETAILED DESCRIPTION

The following description of certain embodiments is merely exemplary in nature and is in no way intended to limit the scope of the disclosure or its applications or uses. In the following detailed description of embodiments of the present systems and methods, reference is made to the accompanying drawings which form a part hereof, and which are shown by way of illustration specific embodiments in which the described systems and methods may be practiced. These embodiments are described in sufficient detail to enable those skilled in the art to practice presently disclosed systems and methods, and it is to be understood that other embodiments may be utilized and that structural and logical changes may be made without departing from the spirit and scope of the disclosure. Moreover, for the purpose of clarity, detailed descriptions of certain features will not be discussed when they would be apparent to those with skill in the art so as not to obscure the description of embodiments of the disclosure. The following detailed description is therefore not to be taken in a limiting sense, and the scope of the disclosure is defined only by the appended claims.

Information in a memory array may be accessed by one or more access operations, such as read or write operations. During an example access operation a word line may be activated (or opened) based on a row address and then selected memory cells along that active word line may have their information read or written to based on which bit lines are accessed, which may be based on a column address. When the access operation is over, the word line may be pre-charged to inactivate (or close) the word line.

During an access operation, data is sent and received along data (DQ) terminals. The data is timed based on a data strobe (DQS) signal, a periodic clock signal. The rising (and/or falling) edges of the DQS signal are used to determine when to latch the voltage on the DQ terminal as a bit of information. During normal operations the information along the DQ terminals may represent data (e.g., to be written to the array or read from the array), however there may be certain operations where it is useful to generate mock data along the DQ terminals. The mock data may take the form of a pseudo-random bit stream (PRBS) where it is useful to mimic a random stream of information along one or more of DQ terminals, for example for testing or training purposes.

In an example operation, the memory may be placed into a DQS training mode and may generate a PRBS along the DQ terminals. A controller may compare the timing at which the mock data is received to the edges of the DQS signal and may adjust the timing of the DQS signal in order to ensure that the DQS timing matches the timing with which the mock data is received. This, in turn, will ensure proper alignment of the data and DQS signal during normal operations.

The memory may include one or more linear feedback shift registers (LFSRs) to generate the PRBS when enabled. The LFSRs include a sequence of latches coupled in series, with logic gates coupled along the series in order to alter the inputs and outputs of the latches such that a very long list of states is generated before repeating. A mode register of the memory may store a seed, or initial pattern to load in the LFSR By controlling the seed, different output sequences may be generated. However, there may be a need to increase the variability between different DQ terminals. For example, if multiple DQ terminals are coupled to a same LFSR with a same seed, then they will have matching patterns. It may be useful to increase the inter-DQ terminal variability while minimizing the amount of additional mode register settings and circuits required to do so.

The present disclosure is drawn to apparatuses, systems, and methods for DQ terminal PBRS variation. The memory includes an LFSR circuit with a number of latches in series. A DQ terminal is coupled to a multiplexer which receives the outputs of multiple of the latches in the LFSR circuit. The mode register includes an LFSR variation setting for the DQ terminal which determines which latch the DQ terminal is coupled to. Different DQ terminals may have different LFSR variation settings, which may be set differently. Because of the logic in between latches of the LFSR, the stream of information taken from different latches of the LFSR circuit may be very different from each other, increasing the ability to change the variability between different DQ terminals. In addition, this may minimize the additional circuits or mode register settings required, saving on the space impact. For example, the LFSR variation settings may be relatively simple multiplexer settings.

In an example implementation, the memory may include two LFSRs, each associated with four DQ terminals out of a set of eight DQ terminals. Each of the two LFSRs may be separately seeded by a setting of the mode register (e.g., a first register with a first seed for the first LFSR and a second register with a second seed for the second LFSR). Within each set of four DQ terminals, a first DQ terminal is coupled through a multiplexer to either a first latch or a second latch of the LFSR circuit, the second DQ terminal is coupled through a second multiplexer to either a third or a fourth latch of the LFSR circuit, the third DQ terminal is coupled through a third multiplexer to either a fifth or a sixth latch of the LFSR circuit, and the fourth DQ circuit is coupled through a fourth multiplexer to either a seventh or an eighth latch of the LFSR circuit. By controlling the settings between the two groups of four DQ terminals per LFSR circuit, and by controlling the seeds of the two LFSR circuits, each of the DQ terminals may experience a different stream of mock data. In some embodiments, to allow for additional variation, inverter circuits may also be included and may be optionally enabled by settings of the mode register to invert the bit stream for a given DQ when enabled.

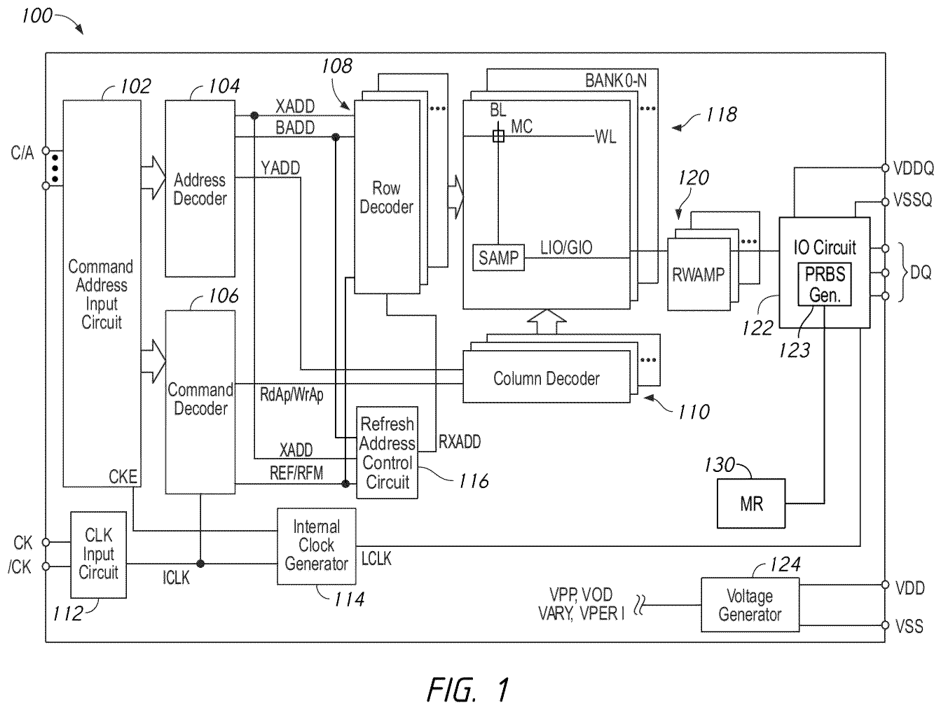

FIG. 1 is a block diagram of a semiconductor device according to at least one embodiment of the disclosure. The semiconductor device 100 may be a semiconductor memory device, such as a DRAM device integrated on a single semiconductor chip. The device 100 may be operated by a controller. The memory receives various commands, data, signals, and voltages (e.g., from the controller).

The semiconductor device 100 includes a memory array 118. The memory array 118 is shown as including a plurality of memory banks. In the embodiment of FIG. 1, the memory array 118 is shown as including eight memory banks BANK0-BANK7. More or fewer banks may be included in the memory array 118 of other embodiments. Each memory bank includes a plurality of word lines WL (rows), a plurality of bit lines BL (columns), and a plurality of memory cells MC arranged at intersections of the plurality of word lines WL and the plurality of bit lines BL. Each memory cell stores information. For example, the memory cell may be a capacitive element which stores a bit of information as an amount of charge on the capacitive element.

The selection of the word line WL is performed by a row decoder 108 and the selection of the bit lines BL is performed by a column decoder 110. In the embodiment of FIG. 1, the row decoder 108 includes a respective row decoder for each memory bank and the column decoder 110 includes a respective column decoder for each memory bank. The bit lines BL are coupled to a respective sense amplifier (SAMP). Read data from the bit line BL is amplified by the sense amplifier SAMP and transferred to read/write amplifiers 120 over local data lines (LIO) and global data lines (GIO). Conversely, write data outputted from the read/write amplifiers 120 is transferred to the sense amplifier SAMP over the GIO and LIO and amplified by the SAMP over the BL to the memory cell at the intersection with the active bit line.

The semiconductor device 100 may employ a plurality of external terminals. The external terminals include command and address (C/A) terminals along a command and address bus to receive commands and addresses. Other external terminals include clock terminals to receive clocks CK and/CK along a clock bus, data terminals DQ to send and receive data along a data bus, and power supply terminals to receive power supply potentials such as VDD, VSS, VDDQ, and VSSQ.

The clock terminals are supplied with external clocks CK and/CK that are provided to an input circuit 112. The external clocks may be complementary. The input circuit 112 generates an internal clock ICLK based on the CK and/CK clocks. The ICLK clock is provided to the command decoder 110 and to an internal clock generator 114. The internal clock generator 114 provides various internal clocks LCLK based on the ICLK clock. The LCLK clocks may be used for timing operation of various internal circuits. For example, the clock signal LCLK may be a divided clock signal which is half the frequency of the external clocks CK and /CK. The internal data clocks LCLK are provided to the input/output circuit 122 to time operation of circuits included in the input/output circuit 122, for example, to data receivers to time the receipt of write data.

The C/A terminals may be supplied with memory addresses. The memory addresses supplied to the C/A terminals are transferred, via a command/address input circuit 102, to an address decoder 104. The address decoder 104 receives the address and supplies a decoded row address XADD to the row decoder 108 and supplies a decoded column address YADD to the column decoder 110. The address decoder 104 may also supply a decoded bank address BADD, which may indicate the bank of the memory array 118 containing the decoded row address XADD and column address YADD. The C/A terminals may be supplied with commands. Examples of commands include timing commands for controlling the timing of various operations, access commands for accessing the memory, such as read commands for performing read operations and write commands for performing write operations, as well as other commands and operations. The access commands may be associated with one or more row address XADD, column address YADD, and bank address BADD to indicate the memory cell(s) to be accessed.

The commands may be provided as internal command signals to a command decoder 106 via the command/address input circuit 102. The command decoder 106 includes circuits to decode the internal command signals to generate various internal signals and commands for performing operations. For example, the command decoder 106 may provide a row command signal to select a word line and a column command signal to select a bit line.

As part of an example read operation, the device 100 may receive a read command along with memory addresses which indicate where the read command should be performed. Responsive to internal commands (such as a row activate command ACT) issued by the command decoder 106, the word line selected by XADD is activated by the row decoder 108 and the data on the memory cells along that word line is amplified onto the intersecting bit lines by sense amplifiers (SAMP). Responsive to internal commands and the column address YADD, the column decoder 110 couples selected bit lines through local and global input/output lines (LIO and GIO) to the read/write amplifiers 120. The read/write amplifiers 120 provide the data to the IO circuit 122, which provides the data along one or more DQ terminals. The data may be provided in synchronization with a data strobe clock DQS.

As part of an example write operation, the device 100 may receive a write command along with memory addresses which indicate where the write command should be performed. Responsive to internal commands (such as a row activate command ACT) issued by the command decoder 106, the word line selected by XADD is activated by the row decoder 108 and the data on the memory cells along that word line is amplified onto the intersecting bit lines by sense amplifiers (SAMP). Responsive to internal commands and the column address YADD, the column decoder 110 couples selected bit lines through local and global input/output lines (LIO and GIO) to the read/write amplifiers 120. The IO circuit 122 receives data along the DQ terminals and provides it to the read write amplifiers 120. The data is provided along the LIO/GIO to the selected bit lines where it is written to the memory cells at the intersections with the active word line.

The memory device 100 includes a mode register 130. The mode register 130 includes one or more storage elements which store information about the memory 100. The storage elements of the mode register 130 may be organized into registers, each of which stores one or more pieces of information such as settings, conditions (e.g., measured temperature), error codes, and so forth.

The IO circuit 122 also includes a PRBS generator circuit 123. The PRBS generator circuit 123 may be activated in certain operations and be coupled to the DQ terminals. When active the PRBS generator circuit 123 may take the place of the normal connection to the read/write amplifiers 120 and array 118. For example, multiplexer circuits (not shown) may couple either the read/write amplifiers 120 or the PRBS generator circuit 123 to the DQ terminals. When the PRBS generator circuit is active, it provides a stream of mock data to the DQ terminals. The mock data may be generated based on the output of one or more LFSR circuits of the PRBS generator circuit 123. The mock data may take the form of a string of pseudo-random information, where the pattern of bits takes a very large number of bits to repeat.

As described in more detail herein, the mode register 130 includes a number of registers which may be used to help increase the variability of the mock data provided. For example, the mode register 130 may store LFSR variation settings for the DQ terminals. In some embodiments, the mode register 130 may store an LFSR variation setting for each DQ terminal. In some embodiments, an LFSR variation setting in the mode register 130 may be shared by one or more DQ terminals. In some embodiments, the settings of the mode register 130 may be used to ensure that each DQ terminal within a set (e.g., a set of eight DQ terminals associated with a byte of information) experiences a different stream of pseudo-random bits.

The device 100 may also receive commands causing it to carry out refresh operations. A refresh control circuit 116 may generate refresh address RXADD and the row decoder may refresh the word lines associated with that refresh address RXADD. The memory device 100 may receive a refresh signal REF and perform one or more refresh operations responsive to the refresh signal. In some embodiments, the refresh control circuit 116 may perform different types of refresh operations. For example, the refresh control circuit 116 may perform ‘normal’ refresh operations where the refresh address RXADD is generated using sequence logic, for example to count through the row addresses or the refresh control circuit 116 may perform targeted refresh operations on specific addresses (e.g., the victims of an identified aggressor).

The power supply terminals are supplied with power supply potentials VDD and VSS. The power supply potentials VDD and VSS are supplied to an internal voltage generator circuit 124. The internal voltage generator circuit 124 generates various internal potentials VPP, VARY, VPERI, and the like based on the power supply potentials VDD and VSS supplied to the power supply terminals. The internal potential VPP is mainly used in the row decoder 108, the internal potentials VARY are mainly used in the sense amplifiers SAMP included in the memory array 118, and the internal potential VPERI is used in many peripheral circuit blocks.

The power supply terminals are also supplied with power supply potentials VDDQ and VSSQ. The power supply potentials VDDQ and VSSQ are supplied to the input/output circuit 122. The power supply potentials VDDQ and VSSQ supplied to the power supply terminals may be the same potentials as the power supply potentials VDD and VSS supplied to the power supply terminals in an embodiment of the disclosure. The power supply potentials VDDQ and VSSQ supplied to the power supply terminals may be different potentials from the power supply potentials VDD and VSS supplied to the power supply terminals in another embodiment of the disclosure. The power supply potentials VDDQ and VSSQ supplied to the power supply terminals are used for the input/output circuit 122 so that power supply noise generated by the input/output circuit 122 does not propagate to the other circuit blocks.

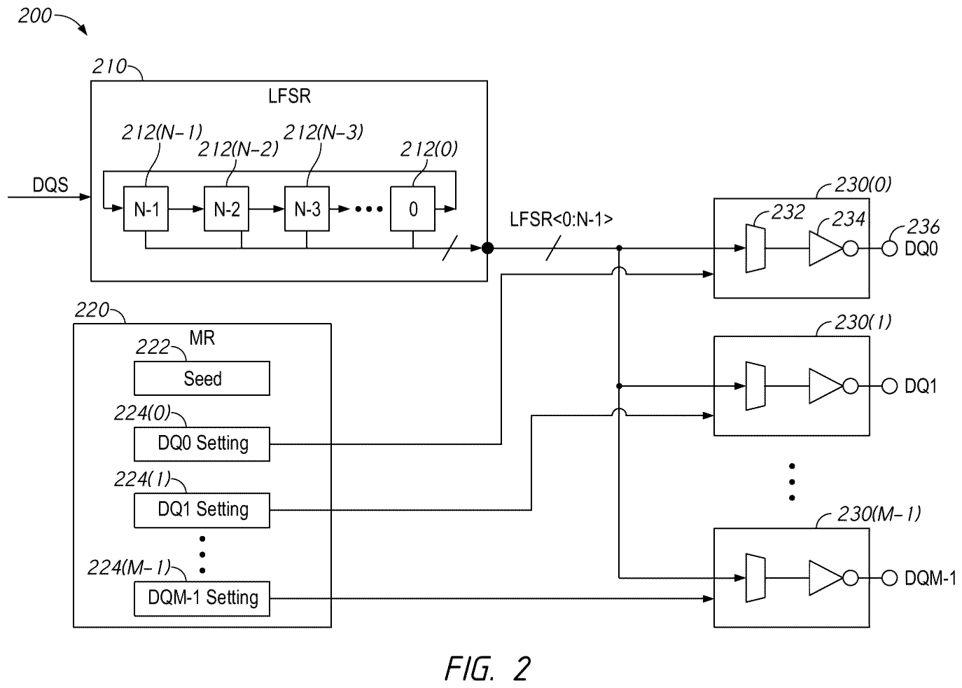

FIG. 2 is a block diagram of a PRBS generator circuit according to some embodiments of the present disclosure. The PRBS generator circuit 200 may, in some embodiments, implement the PRBS generator circuit 123 of FIG. 1. Also shown in FIG. 2 are a mode register 220 (e.g., 130 of FIG. 1) and the DQ terminals 236 to help provide context for the operation of the PRBS generator circuit 200.

The PRBS generator circuit 200 includes an LFSR circuit 210 and a number of LFSR variation circuits 230, each of which is associated with one or more DQ terminals. Also shown is a mode register 220, which stores various settings, such as LFSR variation settings 224, each associated a LFSR variation circuit 230. The LFSR circuit generates a stream of bits using a series of latches 212. The LFSR variation circuits 230 control the stream of bits which reach the associated DQ terminal(s) based on the associated LFSR variation setting 224. For the sake of description, each LFSR variation circuit 230 and LFSR variation setting 224 is shown associated with a single DQ terminal 236, however in other embodiments each LFSR setting 224 and LFSR variation circuit 230 may be associated with other numbers of DQ terminals. Similarly, FIG. 2 shows a single LFSR circuit 210, however in other embodiments there may be a first LFSR circuit associated with a first portion of the DQ terminals, a second LFSR circuit associated with a second portion of the DQ terminals and so forth.

The LFSR circuit 210 includes a number of latch circuits 212 which are coupled in a series. In this example there are N latch circuits numbered Latch0 212(0) to LatchN-1 212(N-1). The latches 212 may be coupled in common to a clock signal, here shown as DQS, however different clock signals may be used in other embodiments, and in some embodiments, the clock signal used may be selectable based on the application the PRBS generator circuit is being used for. With each activation (e.g., rising and/or falling edge) of the clock signal, the bits are shifted through the latches in series from LatchN-1 to LatchN-2 and so forth until Latch0 and then from Latch0 back to LatchN-1. Not shown in FIG. 2 are various additional circuits, such as logic gates, which are used to vary the state of a bit as it travels through the series of latches. For example, certain latches may have an XOR gate between them, which has a first input coupled to the output of the previous latch, a second input coupled to the output of a different latch in the series (e.g., Latch0), and an output coupled to the next latch. Accordingly, if a bit starts at a first state (e.g., a logical high), it may change states as it moves through the sequence of latches in the LFSR circuit 210. In this manner, the pattern of bits experienced by any given latch may take a relatively large number of clock cycles to repeat.

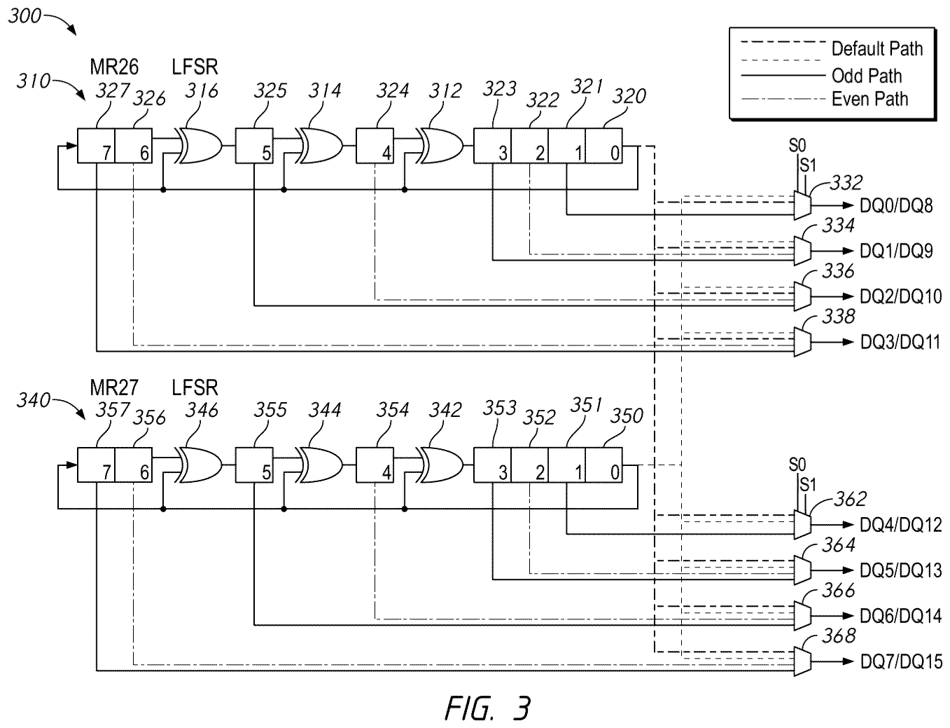

The PRBS generator circuit 200 includes a number of LFSR variation circuits 230. In the example implementation of FIG. 3, each LFSR variation circuit 230 is associated with one of M DQ terminals 236, here labeled DQ0 to DQM-1. Accordingly, there are M LFSR variation circuits 230(0) to 230(M-1). Since the LFSR variation circuits 230 may generally be similar to each other, only the components of one circuit, LFSR variation circuit 230(0) are described in detail herein.

The LFSR variation circuit 230 include a multiplexer 232, an optional inverter 234, and provide an output to a DQ terminal 236. The multiplexer 232 receives signals from multiple latches 212 of the LFSR circuit 210. For example, in the embodiment of FIG. 2, the LFSR circuit 210 provides an N bit signal LFSR<0:N-1> where each bit of the signal LFSR is the output of the a corresponding latch. So the bit LFSR<0> is the current output of Latch0 212(0), the bit LFSR<1> is the output of the Latch1, and so forth. The states of one or more of the bits of the signal LFSR may change with the activations of the clock signal (in this case DQS).

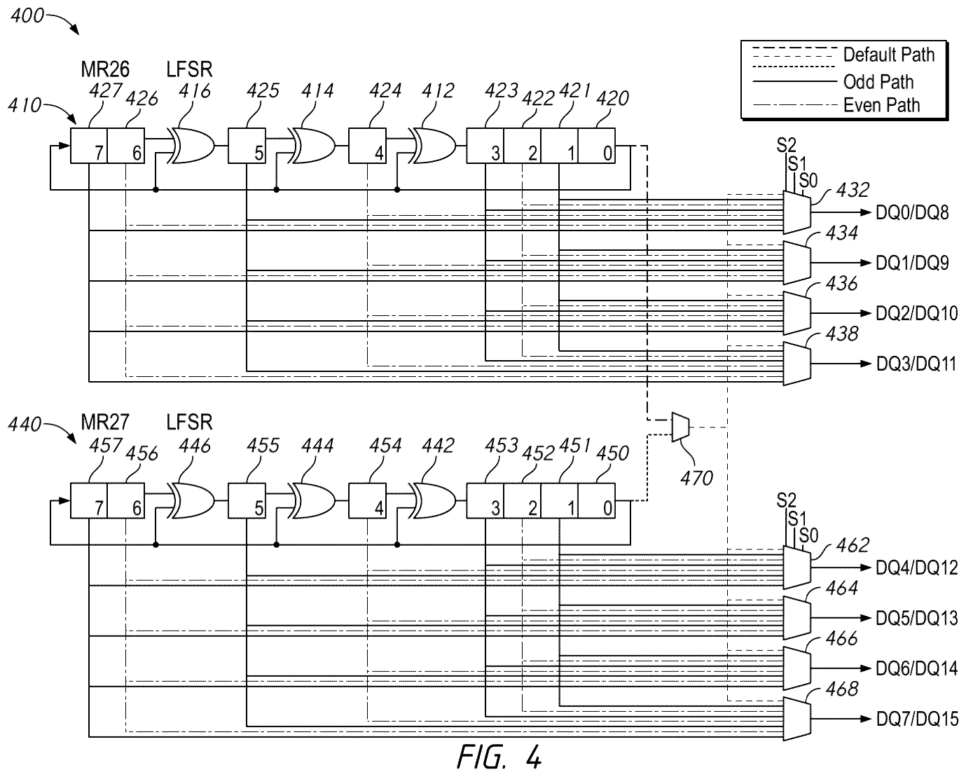

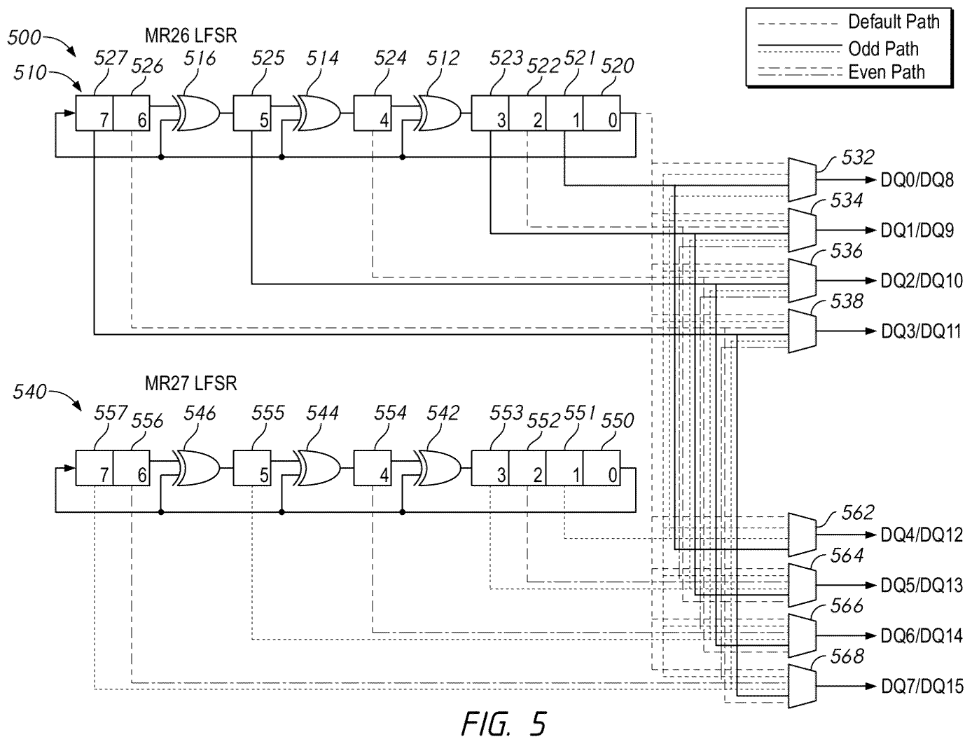

In the embodiment of FIG. 2, each bit of the LFSR signal is provided to each of the LFSR variation circuit 230(0) to 230(M-1). However, in other example embodiments, different subsets of the bits of the LFSR signals (e.g., different subsets of the bits from the latches 212) are provided to different of the LFSR variation circuits 230. For example, a first multiplexer in a first LFSR variation circuit may receive a first subset of the bits, a second multiplexer in a second LFSR variation circuit may receive a second subset of the bits and so forth. In some embodiments, the subsets may overlap. In some embodiments, the subsets may be non-overlapping. FIG. 3 shows an example implementation with non-overlapping subsets in more detail. FIG. 4 shows an example implementation where each LFSR variation circuit receives each of the bits of the LFSR signal in more detail. In some embodiments, the LFSR variation circuits may have inputs which crossover between different LFSR circuits. FIG. 5 shows an example implementation where the LFSR variation circuits receive inputs from latches of different LFSR circuits.

The mode register 220 includes a number of LFSR variation settings 224, each of which is associated with one of the LFSR variation circuits 230. The LFSR variation settings 224 may include a setting for the multiplexer 232. Based on a multiplexer setting of the LFSR variation setting for that LFSR variation circuit, the multiplexer 232 selects one of the bits that it receives of the LFSR signal to provide as the output of the multiplexer 232. In some embodiments, the LFSR circuit 230 includes an optional inverter circuit 234, which may be enabled or disabled based on an inverter setting of the LFSR variation setting 224. If the inverter setting is enabled, then the inverter circuit 234 may invert a state of the output of the multiplexer 232 (e.g., the selected latch signal) before it is passed to the associated DQ terminal. If the inverter setting is disabled, then the output of the multiplexer is passed as-is to the DQ terminal.

In some embodiments, when LFSR variation circuit 230 is shared by multiple DQ terminals, the multiplexer 232 may be shared between the DQ terminals, but each DQ terminal may have its own inverter circuit 234. Accordingly, each DQ terminal may also have its own inverter setting. In this manner, even though the DQ terminals may share the stream from the multiplexer 232, the different inverter settings may be used to vary the stream experienced by the DQ terminals.

The mode register 220 may include other settings relevant to the operation of the PRBS generator circuit 200. For example, the mode register 220 may include a seed 222, which may be an initial value or values loaded into the LFSR circuit 210. The seed 222 may initialize a starting state of the LFSR circuit 210. In embodiments where there are multiple LFSR circuits 210, each may have a corresponding seed stored in the mode register. While not shown in FIG. 2, the mode register 220 may store additional information or settings useful to the PRBS generator circuit 200. For example, the mode register 220 may include a PRBS enable register, which may activate the PRBS generator circuit 200 and cause it to begin providing bits to the DQ terminals (rather than the memory array).

FIG. 3 is a schematic diagram of a PRBS generator circuit with non-overlapping latch selection according to some embodiments of the present disclosure. The PRBS generator circuit 300 may, in some embodiments, implement the PRBS generator circuit 123 of FIG. 1 and/or 200 of FIG. 2. In the embodiment of FIG. 3, each LFSR variation circuit (in this embodiment multiplexers 332-338 and 362-368) receives two inputs, from a first latch and a second latch, and the latches that the LFSR variation circuits can select between do not overlap (e.g., each LFSR variation circuit receives inputs from different pairs of latches).

The PRBS generator circuit 300 includes a first LFSR circuit 310 and a second LFSR circuit 340. Both LFSR circuits 310 and 340 include a number of latches (320-327 in LFSR 310 and 350-357 in LFSR 340). Also included in the LFSR circuits 310 and 340 are logic gates which are used to vary the state of bits as they progress through the latches. For example, the LFSR circuit 310 includes XOR gates 312-316 and the LFSR circuit 340 includes XOR gates 342-346. The LFSR circuits 310 and 340 provide outputs from their respective latches to a set of LFSR variation circuits, implemented in FIG. 3 as multiplexers 332-338 and 362-368 which in turn are coupled to the DQ terminals. Each of the multiplexers 332-338 and 362-368 are coupled to a different pair of the latches 320-327 or 350-357. The multiplexers 332-338 and 362-368 select which latch value to provide as the output based on respective LSFR variation settings (e.g., 224 of FIG. 2) which in turn may be used to set the value of one or more select signals such as S0 and S1.

The two LFSR circuits 310 and 340 may be structurally similar to each other. For the sake of brevity only the first LFSR circuit 310 will be described in detail. The first LFSR circuit 310 includes a series of eight latches 320-327 (e.g., 212 of FIG. 2). The output of each latch is coupled to an input of the next latch in the series (except for those which have logic gates in between), so the output of Latch7 327 provides an input of Latch6 326 and so forth until Latch0 320, which is coupled to the input of Latch 327. In addition to the series of latches 320-327, there are three XOR gates 312-316, which are used to vary the value of the bits. The first XOR gate 312 is coupled between Latch4 324 and Latch3 323, with a first input terminal coupled to the output of Latch 4 324 and a second input terminal coupled to the output of Latch0 320. The output of the first XOR gate 312 is coupled the input of Latch3 323. The second XOR gate 314 is coupled between Latch5 324 and Latch4 324, with a first input terminal coupled to the output of Latch5 325 and a second input terminal coupled to the output of Latch0 320. The output of the second XOR gate 314 is coupled the input of Latch4 324. The third XOR gate 316 is coupled between Latch6 326 and Latch5 325, which a first input terminal coupled to the output of Latch5 325 and a second input terminal coupled to the output of Latch0 320. The output of the third XOR gate 316 is coupled to the input of Latch5 325. The second LFSR circuit 340 may be similarly laid out with latches 350-357 and XOR gates 342-346.

Although the two LFSR circuits 310 and 340 may be structurally similar, they may produce different bit streams based on the way they are initialized. For example, the first LFSR circuit 310 may be initialized with a first seed and the second LFSR circuit 340 may be initialized with a second seed. The first seed may be stored in a first register of the mode register and the second seed may be stored in a second register of the mode register. In an example embodiment, the first LFSR circuit 310 may be initialized by a seed in MR26, while the second LFSR circuit 340 may be initialized by a seed in MR27. Other registers may be used in other example embodiments.

The embodiment of FIG. 3 shows sixteen DQ terminals, split into two bytes, with DQ0-DQ7 part of a first byte and DQ8-DQ15 part of a second byte. Each LFSR variation circuit, or multiplexer in this embodiment, is coupled to a bit in the first byte and a bit in the second byte. So the multiplexer 332 is coupled to DQ0 and DQ8, the multiplexer 334 is coupled to DQ1 and DQ9, the multiplexer 336 is coupled to DQ2 and DQ10, the multiplexer 338 is coupled to DQ3 and DQ11, the multiplexer 362 is coupled to DQ4 and DQ12, the multiplexer 364 is coupled to DQ5 and DQ13, the multiplexer 366 is coupled to DQ6 and DQ14, and the multiplexer 368 is coupled to DQ7 and DQ15.

The multiplexers 332-338 (e.g., DQ0-DQ3 and DQ8-DQ11) are coupled to the latches of the first LFSR circuit 310. The multiplexers 362-368 (e.g., DQ4-DQ7 and DQ12-DQ15) are coupled to the latches of the second LFSR circuit 340. The multiplexer 332 is coupled to Latch1 321 of the first LFSR 310 (as well as to Latch0 320 through a default path). The multiplexer 334 is coupled to Latch2 322 and Latch3 323. The multiplexer 336 is coupled to Latch4 324 and Latch5 325. The multiplexer 338 is coupled to Latch6 326 and Latch7 327. The multiplexer 362 is coupled to Latch 1 351 of the second LFSR (as well as to Latch0 350 through a default path). The multiplexer 364 is coupled to Latch2 352 and Latch3 353. The multiplexer 366 is coupled to Latch4 354 and Latch5 355. The multiplexer 368 is coupled Latch6 356 and Latch7 357.

Each of the multiplexers receives one or more signals (e.g., S0 and/or S1) from a respective LFSR variation setting to determine the output of which of the pair of latches that multiplexer is coupled to is provided as the output of the multiplexer to the coupled DQ terminals. In the embodiment of FIG. 3, since there are two latches provided to each multiplexer, then the LFSR variation setting may be a one-bit value (e.g., S0 alone), which selects between the even numbered one of the coupled pair of latches or the odd numbered one of the coupled pair of latches. By selecting different values for the LFSR variation settings and different seeds for the two LFSR circuits 310 and 340, the DQ terminals in cach byte may experience a different stream of bits.

FIG. 3 also shows optional settings which may be used for a first and a second ‘default’ path to each of the multiplexers. The first default path is a setting in which the multiplexers 332-338 and 362-368 pass the output of Latch0 320 of the first LFSR circuit 310 to the respective DQ terminals, while the second default path is a setting in which the multiplexers 332-338 and 362-368 pass the output of Latch0 350 of the second LFSR circuit 340 to the respective DQ terminal. The two default settings may be allowed for additional options in increasing the variability between DQ terminals of a byte. In embodiments where the two default paths are included, then the LFSR variation settings may be two bit values (e.g., both S0 and S1), since there are four possible inputs to each multiplexer. If the default path is not used, then the two Latch0′s 320 and 350 may be coupled to multiplexers 332 and 362 respectively as options along an ‘even’ selection path.

Although not shown in FIG. 3, in some embodiments, inverter circuits (e.g., 234 of FIG. 2) may also be used to further increase the variation between the bit streams sent to different DQ terminals. In some embodiments, cach of the two DQ terminals coupled to a single multiplexer may have its own inverter circuit and its own inverter setting. For example, the multiplexer 332 may provide its output to a first inverter circuit associated with DQ0 and a second inverter circuit associated with DQ8. Each inverter circuit may be activated by a separate inverter setting in the LFSR variation setting for that DQ circuit.

FIG. 4 is a schematic diagram of a PRBS generator circuit with overlapping latch selections according to some embodiments of the present disclosure. The PRBS generator circuit 400 may, in some embodiments implement the PRBS generator circuit 123 of FIG. 1 and/or 200 of FIG. 2. The PRBS generator circuit 400 may be generally similar to the PRBS generator circuit 300 of FIG. 3, except that the PRBS generator circuit 400 has multiplexers coupled to the latches in a different fashion than the multiplexers of the PRBS generator circuit 300. For the sake of brevity, certain details already described with respect to FIG. 3 will not be repeated with respect to FIG. 4.

In the embodiment of FIG. 4, each of the multiplexers 432-438 has eight input terminals. If an optional default path is not used, then the multiplexers 432-438 are each coupled to all of the latches 420-427 of the first LFSR circuit 410, and the multiplexers 462-468 are cach coupled to all of the latches 450-457 of the second LFSR circuit 440. Accordingly, since there are eight latch signals to select between, the LSFR variation setting for each multiplexer may be a three bit signal. For example, select signals S0, S1, and S2 are used to set which input cach multiplexer provides to the respective DQ terminal.

In embodiments where the optional default path is a feature, then an extra multiplexer 470 may be included. The multiplexer 470 receives the outputs of Latch0 420 from the first LFSR circuit 410 and Latch0 450 from the second LFSR circuit 440. The multiplexer 470 provides an output to each of the multiplexers 432-438 and 462-468. The output of the multiplexer 470 is coupled to one of the input terminals of the multiplexers 432-438 and 462-468 instead of the output of Latch0 420 or 450 respectively. Accordingly, by enabling a default mode (e.g., by setting S0-S2 to a value that causes the multiplexers 432-438 and 462-468 to pass the value output by the multiplexer 470), the output from the multiplexer 470 may be provided to the DQ terminals, and the multiplexer 470 may select whether it is the output from the first LFSR circuit 410 or the second LFSR circuit 440. The multiplexer 470 may coupled to a select signal (not shown) which determines which input is passed.

In this manner, by varying the settings between the multiplexers 432-438 and 462-468, any of the first set of DQ terminals in a given byte (e.g., DQ0-DQ3) may be coupled to any of latches of the first LFSR circuit 410 and any of the second set of DQ terminals in the byte (e.g., DQ4-DQ7) may be coupled to any of the latches in the second LFSR circuit 440. This may allow for greater variation of the bit streams along the DQ terminals.

FIG. 5 is a schematic diagram of a PRBS generator circuit with crossover selection between two LFSR circuits according to some embodiments of the present disclosure. The PRBS generator circuit 500 may, in some embodiments implement the PRBS generator circuit 123 of FIG. 1 and/or 200 of FIG. 2. The PRBS generator circuit 500 may be generally similar to the PRBS generator circuits 300 of FIG. 3 and/or 400 of FIG. 4, except that the PRBS generator circuit 500 has multiplexers coupled to the latches in a different fashion than the multiplexers of the PRBS generator circuit 300 and the PRBS generator circuit 400. For the sake of brevity, certain details already described with respect to FIG. 3 and FIG. 4 will not be repeated with respect to FIG. 5.

The PRBS generator circuit 500 includes two different LFSR circuits 510 and 540. In the example embodiment of FIG. 5, the multiplexers 532-538 and 562-568 have the option of selecting the output of one of the latches from either the first or the second LFSR circuits 510 and 540. In general, each of the multiplexers is coupled to two latches in the associated LFSR circuit, similar to the couplings of FIG. 3, but is also coupled to the equivalent two latches in the other LFSR circuit. For example, the multiplexer 534 may select between the outputs of latches 523 or 522 of the first LFSR circuit 510 or the outputs of latches 553 and 552 of the second LFSR circuit 540.

By allowing selection which crosses over between the two LFSR circuits, increased variability of the outputs of the DQ terminals may be selected. For example, since the two LFSR circuits 510 and 540 may be seeded separately, the ability to select from either the first or the second LFSR may increase the potential variability of the output to the given DQ terminal.

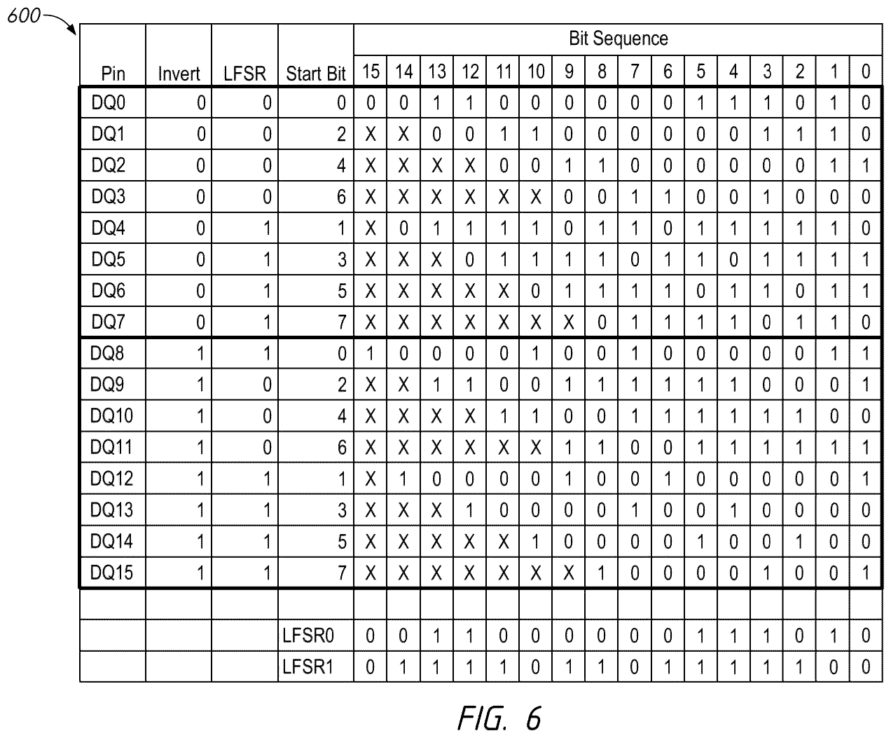

FIG. 6 is a table of example operations of a PRBS generator circuit according to some embodiments of the present disclosure. The table 600 shows the settings and the resulting stream of bits along 16 DQ terminals coupled to the PRBS generator circuit 500 of FIG. 5. The table 600 shows a first column which labels the pin or DQ terminal for a given row.

The next three columns represent the LFSR variation settings used for that DQ terminal. The second column shows an inversion enable bit which determines whether the output of the multiplexer (e.g., 332-338 and 362-368 of FIG. 3) will be inverted for that DQ terminal. In the example of table 600, the DQ terminals of the first byte DQL0-DQL7 have the invert enable bit inactive, while the DQ terminals of the second byte DQU0-DQU7 have their invert enable bit activated. Accordingly, two DQ terminals which share a multiplexer (e.g., DQL0 and DQU0) would still have different output streams, with one being the inverse of the other. The next two columns show the multiplexer select bit (here labelled LFSR) and then an additional column (labelled ‘start bit’) which indicates which latch of the LFSR is indicated by the state of the multiplexer select bit.

The remaining columns of the table show the sequence of bits experienced by the different DQ terminals over a sequence of 16 clocks (e.g., rising and/or falling edges of DQS). The steam of bits is different for each of the 16 DQ terminals due to the different seeding of the two LFSR circuits and the different settings of the invert enable bits and multiplexer select bits for the different DQ terminals.

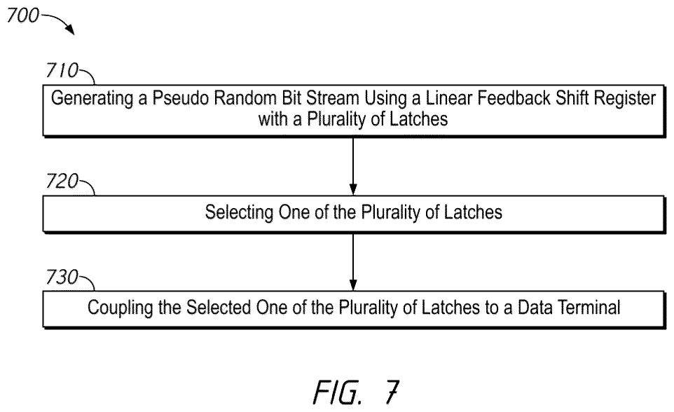

FIG. 7 is a flow chart of a method according to some embodiments of the present disclosure. The method 700 may, in some embodiments, be performed by one or more of the systems and/or apparatuses described herein. For example, the method 700 may be implemented by a PRBS generator circuit such as 123 of FIG. 1, 200 of FIG. 2, 300 of FIG. 3, 400 of FIG. 4, and/or 500 of FIG. 5.

The method 700 may generally begin with block 710, which describes generating a PRBS using an LFSR (e.g., 210 of FIG. 2, 310/340 of FIG. 3, 410/440 of FIG. 4, and/or 510/540 of FIG. 5) with a plurality of latches (e.g., 212 of FIG. 2, 320-327/350-357 of FIG. 3, 420-427/450-457 of FIG. 4, and/or 520-527/550-557 of FIG. 5). The method 700 may include initializing the LFSR based on a seed (e.g., 222 of FIG. 2) stored in a mode register (e.g., 130 of FIG. 1 and/or 220 of FIG. 2). The method 700 may include generating the PRBS in synchronization with rising and/or falling edges of a clock signal. For example, the method 700 may include providing the clock signal in common to clock terminals of the plurality of latches.

Block 710 is followed by block 720, which describes selecting one of the plurality of latches. The selecting may be based on a setting in a mode register, such as the LFSR variation settings 224 of FIG. 2. The selecting may include selecting between a first latch and a second latch (e.g., as shown in the example embodiment of FIG. 3) or selecting one out of all of the plurality of latches (e.g., as shown in the example embodiment of FIG. 4). The selecting may include selecting an input of a multiplexer circuit (e.g., 232 of FIG. 2) and providing the selected input as the output of the multiplexer.

Block 720 is followed by block 730, which describes coupling the selected one of the plurality of latches to a data terminal. For example, the method 700 may include providing the output of the multiplexer to the data terminal. In some embodiments, the method 700 may include providing the output to multiple data terminals. In some embodiments, the method 700 may include inverting the output of the selected one of the plurality of latches and providing the inverted output to the data terminal. The method may include selecting whether to invert or not based on an inverter setting.

In some embodiments, the method 700 may include providing a different stream of bits to each of a plurality of data terminals in a set (e.g., in a byte). For example, the method 700 may include selecting different of the plurality of latches for each of the plurality of data terminals in the set. In some embodiments, the method 700 may include coupling latches from a first LFSR circuit to a first portion of the data terminals in the set and coupling latches from a second LFSR circuit to a second portion of the data terminals in the set.

It is to be appreciated that any one of the examples, embodiments or processes described herein may be combined with one or more other examples, embodiments and/or processes or be separated and/or performed amongst separate devices or device portions in accordance with the present systems, devices and methods.

Finally, the above-discussion is intended to be merely illustrative of the present system and should not be construed as limiting the appended claims to any particular embodiment or group of embodiments. Thus, while the present system has been described in particular detail with reference to exemplary embodiments, it should also be appreciated that numerous modifications and alternative embodiments may be devised by those having ordinary skill in the art without departing from the broader and intended spirit and scope of the present system as set forth in the claims that follow. Accordingly, the specification and drawings are to be regarded in an illustrative manner and are not intended to limit the scope of the appended claims.

What is claimed is:

1. An apparatus comprising:
a linear feedback shift register (LFSR) comprising a plurality of latch circuits;
a multiplexer with a first input terminal coupled to one of the plurality of latch circuits and a second input terminal coupled to another of the plurality of latch circuits, wherein the multiplexer is configured to couple the first input terminal or the second input terminal to an output terminal; and
a data terminal coupled to the output terminal of the multiplexer.

2. The apparatus of claim 1, further comprising a mode register configured to store a LFSR variation setting associated with the data terminal, wherein the LFSR variation setting specifies the first input terminal or the second input terminal.

3. The apparatus of claim 2, wherein the mode register is further configured to store an LFSR seed, and wherein the LFSR is initialized based on the LFSR seed.

4. The apparatus of claim 1, further comprising an inverter circuit configured to selectively invert the information from the output terminal of the multiplexer before providing the information to the data terminal.

5. The apparatus of claim 1, further comprising:
a second multiplexer with a first input terminal coupled to one of the plurality of latch circuits and a second input terminal coupled to another of the plurality of latch circuits, wherein the second multiplexer is configured to couple the first input terminal or the second input terminal of the second multiplexer to an output terminal of the second multiplexer; and
a second data terminal coupled to the output terminal of the second multiplexer.

6. The apparatus of claim 1, wherein the multiplexer includes a plurality of input terminals each coupled to a respective one of the plurality of latch circuits.

7. The apparatus of claim 1, further comprising a second data terminal coupled to the output terminal of the multiplexer, wherein the data terminal is associated with a first byte and the second data terminal is associated with a second byte.

8. The apparatus of claim 1, further comprising
a second LFSR comprising a second plurality of latches;
a second multiplexer with a first input terminal coupled to one of the second plurality of latch circuits and a second input terminal coupled to another of the second plurality of latch circuits, wherein the multiplexer is configured to couple the first input terminal or the second input terminal to an output terminal; and
a second data terminal coupled to the output terminal of the second multiplexer.

9. An apparatus comprising:
a linear feedback shift register (LFSR) circuit comprising a plurality of latch circuits;
a plurality of data terminals; and
a plurality of LFSR variation circuits, each associated with one of the plurality of data terminals, wherein each of the plurality of LFSR variation circuits is configured to couple the associated one of the plurality of data terminals to a selected one of the plurality of latch circuits based on a respective one of a plurality of LFSR variation settings.

10. The apparatus of claim 9, further comprising:
a second LFSR circuit comprising a second plurality of latch circuits;
a second plurality of data terminals, wherein the plurality of data terminals and the second plurality of data terminals are associated with a same byte; and
a second plurality of LFSR variation circuits, each associated with one of the second plurality of data terminals, wherein each of the second plurality of LFSR variation circuits is configured to couple the associated one of the second plurality of data terminals to a selected one of the second plurality of latch circuits based on a respective one of a second plurality of LFSR variation settings.

11. The apparatus of claim 10, further comprising:
a third plurality of data terminals each associated with one of the plurality of LFSR variation circuits; and
a fourth plurality of data terminals each associated with one of the second plurality of LFSR variation circuits, wherein the third and the fourth plurality of data terminals are associated with a same second byte different than the byte that the first and the second plurality of data terminals are associated with.

12. The apparatus of claim 9, wherein each of the plurality of LFSR variation circuits includes a multiplexer circuit with at least two input terminals coupled to at least two of the plurality of latch circuits and an output coupled to the associated one of the plurality of data terminals.

13. The apparatus of claim 12, wherein each of the plurality of LFSR variation circuits includes an inverter circuit configured to selectively invert the output coupled to the associated one of the plurality of data terminals.

14. The apparatus of claim 9, wherein each of the plurality of latches of the LFSR experiences a different pseudo-random bit stream.

15. A method comprising:
generating a pseudo random bit stream (PRBS) using a linear feedback shift register (LFSR) comprising a plurality of latches;
selecting one of the plurality of latches; and
coupling the selected one of the plurality of latches to a data terminal.

16. The method of claim 15, further comprising initializing the LFSR based on a seed.

17. The method of claim 15, further comprising selecting the one of the plurality of latches based on a setting in a mode register.

18. The method of claim 15, further comprising selecting between a first or a second latch of the plurality of latches with a multiplexer.

19. The method of claim 15, further comprising selecting between all of the plurality of latches with a multiplexer.

20. The method of claim 15, further comprising selectively inverting the output of the selected one of the plurality of latches.
